(19) United States
(12) Patent Application Publication
(10) Pub. No.: US 2011/0180316 A1
(43) Pub. Date: Jul. 28, 2011

(54) ELECTRONIC DEVICE AND ELECTRONIC DEVICE HOUSING BODY

(75) Inventor: Takaya NAKAYAMA, Kawasaki (JP)

(73) Assignee: FUJITSU LIMITED, Kawasaki (JP)

(21) Appl. No.: 13/013,009

(22) Filed: Jan. 25, 2011

(30) Foreign Application Priority Data
Jan. 27, 2010 (JP) 2010-15780

(51) Int. Cl. H05K 5/00; H05K 5/02

(52) U.S. Cl. 174/520; 312/223.1

(57) ABSTRACT

An electronic device fixed to a pair of rack columns that are separated by a certain distance. The electronic device includes a housing that includes side surfaces, each of the side surfaces opposing one of the rack columns when the housing is sandwiched between the pair of rack columns, and a pair of hook members that are supported slidably in a depth direction on the side surfaces, respectively, and engaged with the mounting hole of the rack columns, respectively.

### CROSS-REFERENCE TO RELATED APPLICATIONS

This application is related to and claims priority to Japanese Patent Application No. 2010-015780, filed on Jan. 27, 2010, and incorporated herein by reference.

### FIELD

Embodiments discussed herein relate to an electronic device fixed to a pair of rack columns, and an electronic device-housing body including a rack and an electronic device housed in the rack.

### BACKGROUND

Typically, a rack has been used for housing an electronic device. Generally, the rack includes a pair of rack columns, and the electronic device housed in the rack is fixed to the pair of rack columns. When two or more electronic devices are housed in a single rack, the electronic devices are longitudinally arranged between the pair of rack columns, and each of the electronic devices is fixed to the rack columns.

As one of methods for fixing the electronic device to rack columns, a method for providing the rack column with two or three mounting holes longitudinally arranged and then mounting the electronic device on the rack by using the mounting holes has been proposed.

Other typical methods for mounting an electronic device on a rack have been proposed (see, Japanese Utility Model Application Laid-open Publication No. 05-20384, Japanese Utility Model Application Laid-open Publication No. 07-22592, and Japanese Patent Application Laid-open Publication No. 2003-110262).

Generally, it is important to keep a desirable workability including when the electronic device is fixed to the rack columns. However, a base onto which the electronic device is placed is used for keeping the desirable workability, thereby undesirably increasing the number of parts for mounting an electronic device on a rack.

### SUMMARY

According to an aspect of an embodiment, an electronic device fixed to a pair of rack columns that is separated by a certain distance is provided. The electronic device includes a housing that includes side surfaces, each of the side surfaces opposing either one of a pair of rack columns when the housing is sandwiched between the pair of rack columns, and a pair of hook members that are supported slidably in a depth direction on the side surfaces, respectively, and the pair of hook members engaged with the mounting hole of the rack columns, respectively.

An embodiment is directed to an electronic device including a housing attachable to a pair of rack columns and a pair of hook members adapted on side surfaces of the housing to adjustably slide to engage and release the housing relative to the pair of rack columns.

Additional aspects and/or advantages will be set forth in part in the description which follows and, in part, will be apparent from the description, or may be learned by practice of the invention.

An object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 a perspective view illustrating a first comparative example;

FIG. 2 a perspective view illustrating a second comparative example;

FIG. 3 is a perspective view illustrating a side surface of an electronic device according to an embodiment;

FIG. 4 is a side view of the electronic device illustrated in FIG. 3;

FIG. 5 is a perspective view illustrating a side surface of an electronic device according to an embodiment;

FIG. 6 is a side view of the electronic device illustrated in FIG. 5;

FIG. 7 is a perspective view of a hook member of the electronic device illustrated in FIGS. 3, 4, 5 and 6;

FIG. 8 is a perspective view illustrating the side surface of the electronic device illustrated in FIG. 3 and one of the rack columns before the electronic device is mounted on the rack columns;

FIG. 9 is a perspective view illustrating an electronic device in an initial state of being mounted on rack columns;

FIG. 10 is a perspective view illustrating a state where an electric device is fixed to rack columns;

FIG. 11 is a perspective view illustrating an electronic device according to an embodiment;

FIG. 12 is a partial perspective view illustrating a portion of the electronic device in FIG. 11 when viewed from another angle;

FIG. 13 is a schematic cross-sectional view illustrating a structure of a second latch section according to an embodiment;

FIG. 14 is a schematic cross-sectional view illustrating a latch section according to an embodiment.

### DETAILED DESCRIPTION

Reference will now be made in detail to the embodiments, examples of which are illustrated in the accompanying drawings, wherein like reference numerals refer to the like elements throughout. The embodiments are described below to explain the present invention by referring to the figures.

The following first describes comparative examples that are compared with embodiments. After that, the embodiments are described.

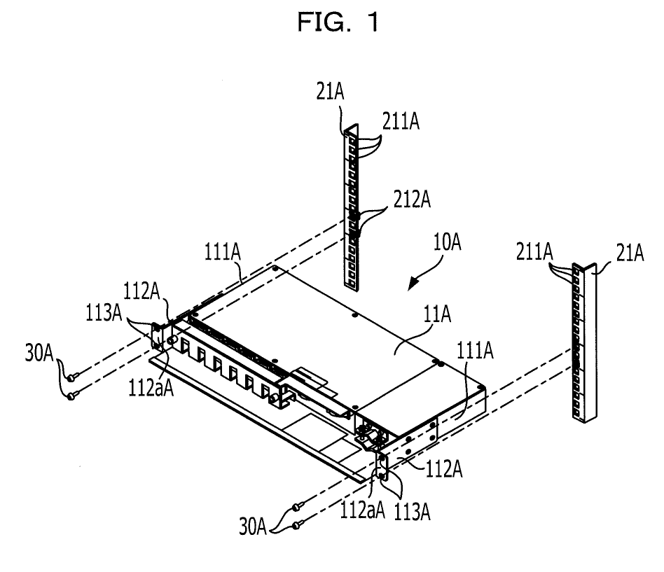

FIG. 1 is a perspective view illustrating a first comparative example.

In FIG. 1, an electronic device 10A and a pair of rack columns 21A related to fixing of the electronic device 10A in a rack that houses the electronic device 10A are illustrated.

The rack columns 21A is erected at left and right sides of the electronic device 10A and the rack columns 21A are separated by a distance that is relatively larger than a width dimension of the electronic device 10A. The rack column 21A is provided with two or more mounting holes 211A that are longitudinally arranged.

A pair of fixing hardware 112A is screwed to each left and right side surfaces 111A of a housing 11A of the electronic device 10A. The fixing hardware 112A includes a collar portion 112aA and screw holes 113A are formed on the collar portion 112aA as illustrated in FIG. 1.

In each of the rack columns 21A, mounting hardware 212A provided with a screw hole is hooked on the back of the mounting hole 211A located at a desirable height position where the electronic device 10A is fixed. The rack column 21A is screwed to the mounting hardware 212A through the screw holes 113A and the mounting hole 211A with a screw 30A so that rack column 21A is sandwiched between the collar portion 112aA of the fixing hardware 112A and the mounting hardware 212A. As a result, the electronic device 10A is fixed to the pair of rack columns 21A.

In this case, when an operator who may be a user fixes the electronic device 10A to the pair of rack columns 21A, the operator generally supports the electronic device 10A from the bottom of the electronic device 10A with one hand undesirably while threadably mounting electronic device 10A on the rack columns with another hand. Thus, such structure for fixing the electronic device to rack columns causes an undesirable workability. In addition, when another electronic device has been already fixed to the rack columns 21A just beneath the electronic device 10A, it may be difficult for the operator to put the hand under the electronic device 10A due to the interference of the device beneath the electronic device 10A. As a result, the workability may be further worsened because, for example, the operation to fix the electronic device to rack columns would generally be required to be performed by two operators.

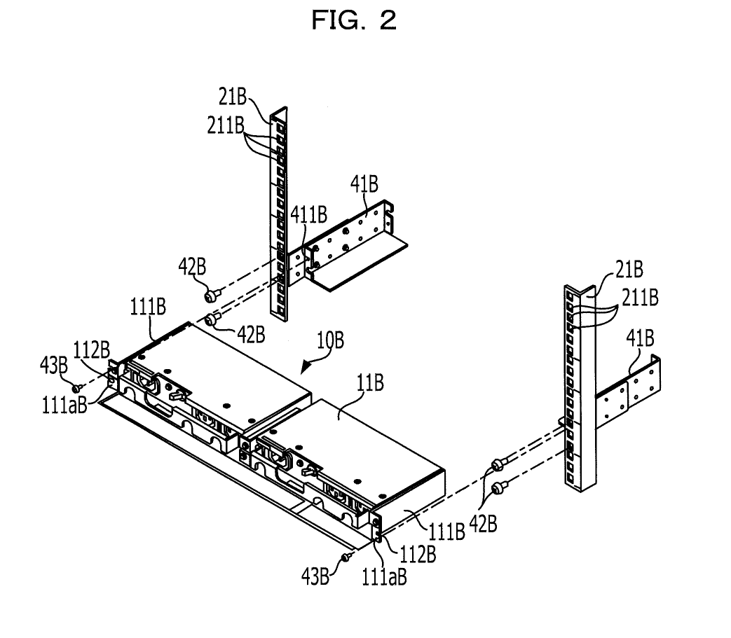

FIG. 2 a perspective view illustrating a second comparative example.

In FIG. 2, an electronic device 10B and a pair of rack columns 21B related to fixing of the electronic device 10B in a rack that houses the electronic device 10B are illustrated as similar to FIG. 1.

The pair of rack columns 21B erected at left and right sides are separated by a distance that is relatively larger than a width dimension of the electronic device 10B. The rack column 21B is provided with two or more mounting holes 211B longitudinally arranged.

A pair of mounts 41B where the electronic device 10B is mounted is threadably fixed, with screw 42B, to a desirable height position where the electronic device 10B is fixed using the mounting holes 211B in the rack columns 21B.

A screw hole 411B is formed on the mount 41B.

A collar portion 111aB including a screw notch 112B is formed on both left and right side surfaces 111B of a housing 11B of the electronic device 10B. The electronic device 10B is mounted on the mounts 41B fixed to the rack columns 21B and screwed to the screw holes 411B through the screw notches 112B with screws 43B. Thus, the electronic device 10B is fixed to the pair of rack columns 21B in a state of being mounted on the mount 41B.

In the second comparative example illustrated in FIG. 2, the electronic device 10B is screwed in the state of being mounted on the mounts 41B, improving the workability of the fixing of the electronic device 10B to rack columns 21B. However, the mount 41B is used as an additional member, undesirably increasing in cost. In addition, two steps of the fixing, that is, the fixing of the mount 41 to the rack column 21B and additionally the fixing of the electronic device 10B to the rack columns 21B is generally performed, so that the desirable workability of fixing is difficult to obtain.

Based on the above-described two comparative examples and problems existing in typical mechanisms, various embodiments are described below.

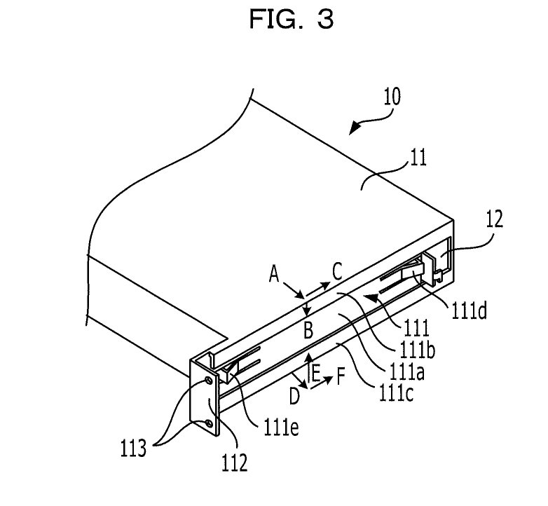

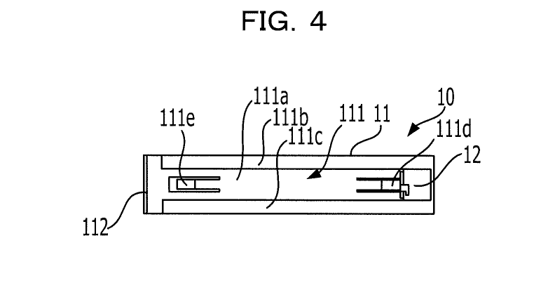

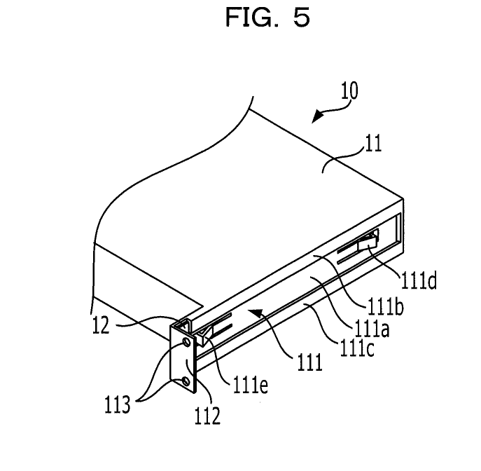

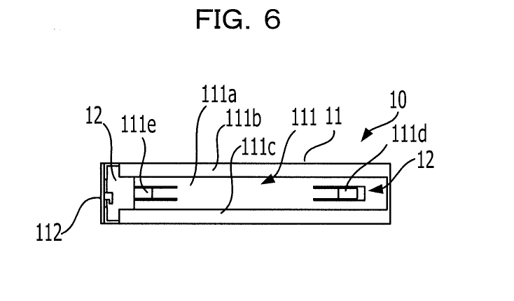

FIG. 3 is a perspective view illustrating a side surface of an electronic device according to an embodiment. FIG. 4 is a side view of the electronic device in FIG. 3. FIG. 5 is a perspective view illustrating a side surface of the electronic device according to an embodiment. FIG. 6 is a side view of the electronic device in FIG. 5. In FIGS. 3 and 4, a hook member 12 is located at a side, that is, a leading side of sliding when the electronic device 10 is housed into a rack (hereinafter, referred to as a far side). In FIGS. 5 and 6, the hook member 12 is located at an opposite side to a far side of the electronic device 10 (hereinafter, referred to as a front side).

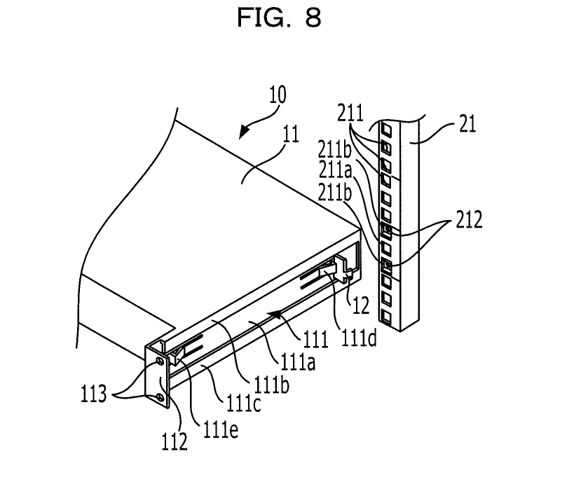

The electronic device 10B is an electronic device that is fixed (linked, joined or attached, etc) to a pair of rack columns 21 (for example, see FIG. 8, however, one of the rack columns 21 is merely illustrated in FIG. 8) similar to the rack columns 21A and the rack columns 21B illustrated in FIGS. 1 and 2 respectively. The pair of rack columns 21 are erected at left and right sides and are separated by a distance similar to the rack columns 21A and the rack columns 21B illustrated in FIGS. 1 and 2, respectively. Two or more mounting holes 211 (see FIG. 8) are longitudinally arranged on the rack column 21. The electronic device 10 is fixed to the rack columns 21 using the mounting holes 211. A side surface 111 of the electronic device 10 is illustrated in FIGS. 3, 4, 5 and 6, however, an opposite side surface of the electronic device 10 also has similar structure to the side surface 111 illustrated in FIGS. 3, 4, 5 and 6. The side surface of the electronic device 10 illustrated in FIGS. 3, 4, 5 and 6 is described in detail below.

A housing 11 of the electronic device 10 includes both side surfaces that are the side surface 111 illustrated in FIGS. 3, 4, 5 and 6 and an opposite side surface having a similar structure. The housing 11 of the electronic device 10 is sandwiched between the pair of the rack columns 21 and causes each of the side surfaces of the electronic device 10 and each of the rack columns 21 to respectively oppose each other. The side surface 111 includes a first surface 111a, a top rail 111b, and a bottom rail 111c. The top rail 111b has a hook shape that is erected on the first surface 111a from an upper edge of the first surface 111a in a direction illustrated by arrow A in FIG. 3, is folded downwardly, and hangs parallel to the first surface 111a in a direction illustrated by arrow B in FIG. 3. In addition, the hook shape of the top rail 111b extends in a depth direction, that is, in a direction illustrated by arrow C in FIG. 3. The bottom rail 111c has a hook shape that the bottom rail 111c erects on the first surface 111a from the lower edge of the first surface 111a in a direction illustrated by arrow D in FIG. 3, is folded upwardly, and rises parallel to the first surface 111a in a direction illustrated by arrow E in FIG. 3. In addition, the hook shape of the bottom rail 111c extends in a depth direction, that is, in a direction illustrated by arrow F in FIG. 3.

The hook member 12 is received between the first surface 111a, the top rail 111b, and the bottom rail 111c. When the hook member 12 is not in a state of being fixed to either latch sections 111d or 111e described in detail below, the hook member 12 may be slidable along the side surface 111 of the housing 11 of the electronic device 10. A first latch section 111d and a second latch section 111e are projecting from the first surface 111a so that the hook member 12 is unslidably held are formed on the first surface 111a. In FIGS. 3 and 4, the hook member 12 is unslidably held at a far side of the side surface 111 by the first latch section 111d. The first latch section 111d is depressed resiliently, for example, with a finger until the first latch section 111d becomes level to the first surface 111a. The hook member 12 becomes slidable by the depression of the first latch section 111d. When the hook member 12 is slid back along the side surface 111 of the housing 11 towards the front side of the electronics device 10, the hook member 12 resiliently depresses the second latch section 111e. When the hook member 12 is further slid to the front side of the electronics device 10 beyond the second latch section 111e, the second latch section 111e projects again as the state illustrated in FIG. 3 and the like, and the hook member 12 is unslidably held at the front side of the side surface 111 as illustrated in FIGS. 5 and 6.

Similar to a case where the hook member 12 is slid to the far side of the side surface, when the hook member 12 is unslidably held by the second latch section 111e as illustrated in FIGS. 5 and 6, the depressing of the second latch section 111d, for example, with the finger causes the hook member 12 to be slidable, and the hook member 12 is slid forward to the far side along the side surface 111. Thus, the first latch section 111d is depressed by the hook member 12. When the hook member 12 is further slid to the far side of the electronic device 10 beyond the first latch section 111d, the first latch section 111d projects again as the state illustrated in FIG. 3 and the like, and the hook member 12 is unslidably held as illustrated in FIGS. 3 and 4. When the electronic device 10 is fixed to the rack column 21 (see FIG. 8), the hook member 12 is relatively moved to the front side of the electronic device 10 because the electronic device 10 is pushed into between the pair of rack column 21. The hook member 12 is unslidably held by the second latch section 111e at the position of the hook member 12 illustrated in FIGS. 5 and 6 when the electronic device 10 is pushed into a fixed position between the pair of rack columns 21.

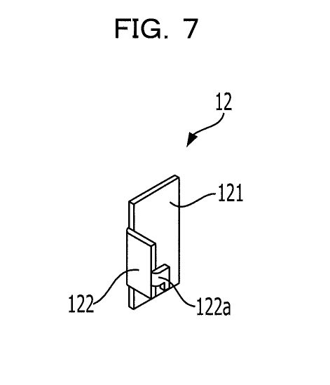

FIG. 7 is a perspective view of the hook member 12 of the electronic device 10 illustrated in FIGS. 3, 4, 5 and 6.

The hook member 12 illustrated in FIG. 7 is a hook member that is adapted to the side surface 111 illustrated in FIGS. 3, 4, 5 and 6, and a hook member that is adapted to the opposite side surface of the electronic device 10 has a shape in symmetry with the hook member illustrated in FIG. 7.

The hook member 12 includes a slide plate 121 and a hook plate 122 as illustrated in FIG. 7. The slide plate 121 is a part that is slidably received between the first surface 111a, the top rail 111b, and the bottom rail 111c in a depth direction, that is, in the direction illustrated by arrows C and F in FIG. 3. As described above, however, the hook member 12 becomes unslidable due to the first latch section 111d and the second latch section 111e. For example, the hook member 12 is stopped at a position when in contact with the first latch section 111d or the second latch section 111e.

The hook plate 122 is placed vertical relative to the first surface 111a (see FIG. 3), erected on the slide plate 121, and projected between the top rail 111b and the bottom rail 111c as illustrated in FIG. 3 and the like. A hook 122a hooked on the mounting hole 211 of the rack column 21 (see FIG. 8) is formed on the hook plate 122.

A method for mounting the electronic device illustrated in FIGS. 3, 4, 5 and 6 on a rack column is described below in detail. A description of only one side surface illustrated in FIGS. 3, 4, 5 and 6 is sufficient for understanding, therefore, only one side surface and only one rack column corresponding to the one side surface are illustrated and described below in detail.

FIG. 8 is a perspective view illustrating the side surface of the electronic device illustrated in FIG. 3 and one of the rack columns before the electronic device is mounted on the rack columns.

Similar to the first comparative example illustrated in FIG. 1, the two or more mounting holes 211 longitudinally arranged are formed on the rack column 21, and, in the rack column 21, mounting hardware 212 where each screw hole is formed are respectively hooked on upper and lower mounting holes 211b sandwiching a single mounting hole 211a at a desirable height position where the electronic device 10 is to be fixed.

The hook member 12 included in the electronics device 10 is moved to a far side of the side surface 111 and is unslidably held by the first latch section 111d.

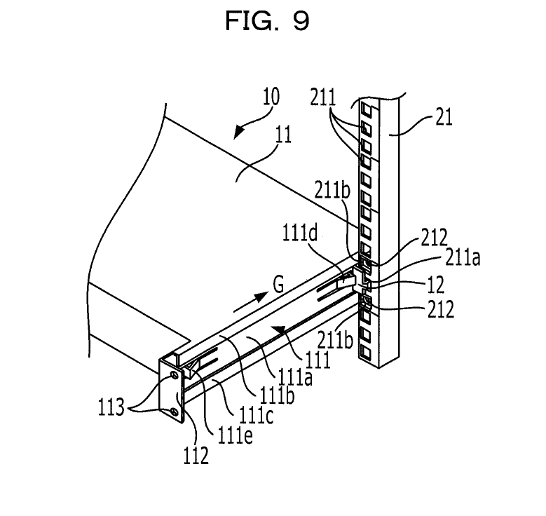

FIG. 9 is a perspective view illustrating the electronic device 10 in an initial state of being mounted on the rack columns 21.

When the electronic device 10 is fixed to the rack columns 21, first, as illustrated in FIG. 9, the hook member 12 located at the far side of the side surface 111 is hooked on the mounting hole 211a between the upper and lower mounting holes 211b where each of the mounting hardware 212 are hooked, on the rack column 21. When an operator releases the electronic device 10 from hand in such state, the electronic device 10 is maintained in a state of being hooked on the rack columns 21. After that, the electronic device 10 is pushed into in a depth direction, that is, in a direction illustrated by arrow G in FIG. 9 as the first latch section 111d is depressed, so that the hook member 12 that has become slidable moves to the front side of the electronic device 10 along the side surface 111 and depressed the second latch section 111e. When the hook member 12 further moves towards the front side of the electronic device 10 beyond the second latch section 111e, the second latch section 111e projects again, so that the hook member 12 is unslidably held by the second latch section 111e. Even when the operator releases the electronic device 10 in a state where the hook member 12 is held by the second latch section 111e, the electronic device 10 is held in a state of being fixed to the rack columns 21.

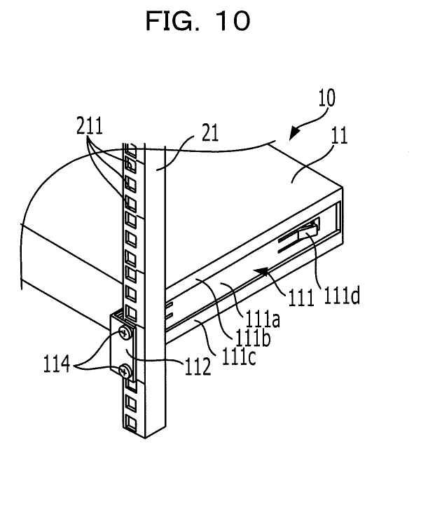

FIG. 10 is a perspective view illustrating a state where the electric device 10 is fixed to the rack columns 21.

After that, the mounting hardware 212 are screwed through a screw holes of the mounting hardware 212, the mounting holes 211b provided on the rack column 21, and holes 113 provided on a collar portion 112 using two screws 114 illustrated in FIG. 10. Thus, the mounting of the electronic device 10 on the rack columns 21 is completed.

When the electronic device 10 is removed from the rack column 21, first, the screws 114 are removed after the state illustrated in FIG. 10, and the electronic device 10 is pulled to the front side while the second latch section 111e is depressed. At the same time, the hook member 12 moves to the far side along the side surface 111, so that the first latch section 111d is pushed down. When the hook member 12 is further move to the far side beyond first latch section 111d, the first latch section 111d projects again, and the hook member 12 is unslidably held by the first latch section 111d as illustrated in FIG. 9. After that, the hook member 12 is removed from the rack column 21 by lifting up the electronic device 10 so as to enable the electronic device 10 to be in a state of being separated from the rack columns 21 as illustrated in FIG. 8.

In the electronic device 10 according to an embodiment, the workability in the mounting of the electronic device 10 on the rack columns 21 may be improved because the operator may perform the operation such as the screwing with both hands.

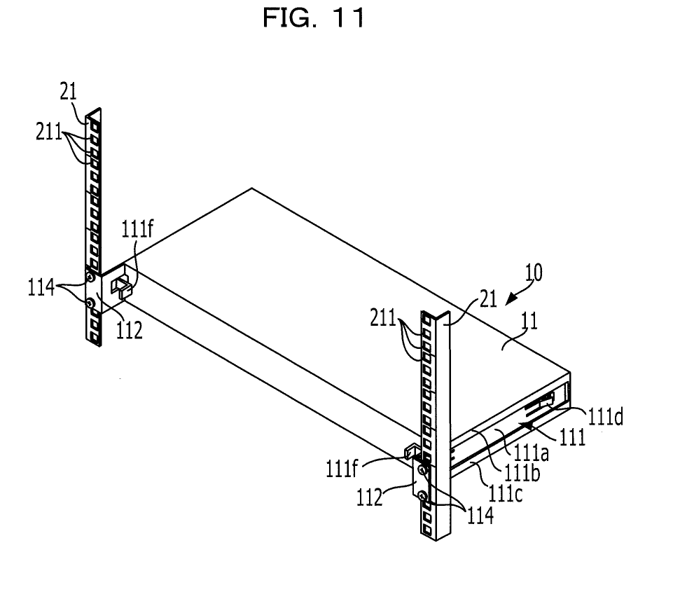

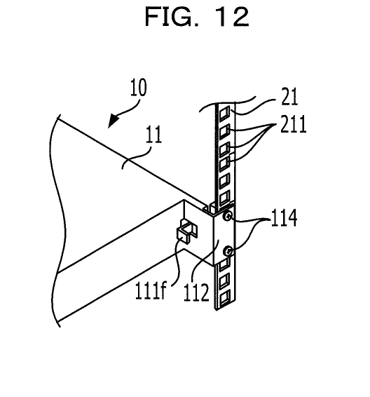

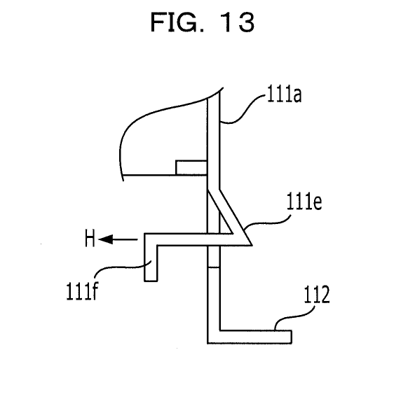

FIG. 11 is a perspective view illustrating an electronic device according to an embodiment. FIG. 12 is a partial perspective view illustrating a portion of the electronic device in FIG. 11 when viewed from another angle. FIG. 13 is a schematic cross-sectional view illustrating a structure of a second latch section according to an embodiment.

In the case of the above-described embodiment, when the operator depresses the second latch section 111e, the operator generally performs the depressing operation by extending the hand around the back side of the rack column 21. Thus, the workability of the removing of the electronic device 10 from the rack columns 21 is also desirable improved.

In an embodiment, as illustrated in FIG. 13, a pull arm 111f is provided on the second latch section 111e in addition to the components according to the above-described embodiment. When the pull arm 111f is pulled in a direction illustrated by arrow H in FIG. 13 by the finger, the second latch section 111e is pulled down until the second latch section 111e becomes level to the first surface 111a. As a result, the fixing of the hook member 12 that has been unslidably fixed by the second latch section 111e is released, and the hook member 12 becomes slidable.

When the pull arm 111f is provided on the second latch section 111e, the operator may operate the second latch section 111e in the front side of the electronic device 10 without extending the hand around the back side of the rack column 21, so that the workability of the removing of the electronics device 10 from the rack column 21 may be improved.

This embodiment in other respects is similar to the above-described embodiment, therefore, redundant descriptions are omitted.

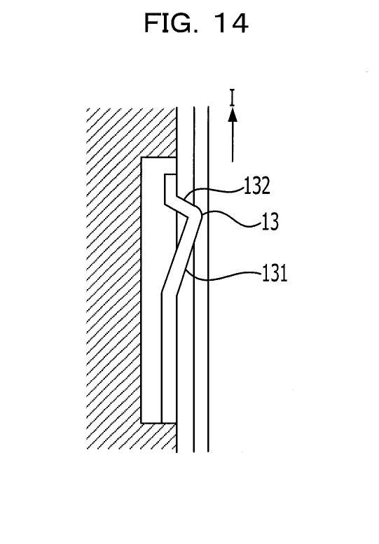

FIG. 14 is a schematic cross-sectional view illustrating a latch section according to an embodiment.

The shape of latch section according to an embodiment is different from a shape of the latch section according to the above-described embodiment. Thus, the latch section according to an embodiment is illustrated and described.

FIG. 14 is a schematic cross-sectional view illustrating a first latch section 13 that corresponds to the first latch section 111d according to the above described embodiment (see FIG. 3) when a direction illustrated by arrow I in FIG. 14 is regarded as the far side of the electronics device 10. The first latch section 13 according to an embodiment includes two beveled surfaces 131 and 132 in the depth direction, that is, in the direction illustrated by arrow G in FIG. 9.

On the other hand, the first latch section 111d according to the above described embodiment includes a beveled surface and a face erecting substantially vertically on the first surface 111a. Thus, the first latch section 111d according to the an embodiment allows the hook member 12 to pass through from the front side to the far side of the electronic device 10 beyond the first latch section 111d, however, the hook member 12 is not allowed to slide from the far side to the front side of the electronic device 10 in the unslidably state due to the first latch section 111d unless the first latch section 111d is depressed, for example, by the finger.

The first latch section 13 illustrated in FIG. 14 includes a beveled surface 132 in the far side of the first latch section 13, so that when a electronic device including the first latch section 13 having the above-described shape is pushed towards the far side, the first latch section 13 is depressed and then the hook member 12 may pass through the first latch section 13.

A first latch section on the opposite side of the electronic device according to an embodiment has a shape where the first latch section 13 illustrated in FIG. 14 is symmetrically reversed. A second latch section has a shape where the first latch section 13 on the same side surface is reversed in the depth direction, that is, in the direction illustrated by arrow G in FIG. 9. Thus, in an embodiment, the hook member is removed from the first latch section by an additional power of push, so that the electronic device may be pushed into between the rack columns. In addition, the hook member is removed from the second latch section by an additional power of pull, so that the electric device may be drawn from between the rack columns.

A housing of an electronic device is provided herein where the housing includes a hook member provided on a leading side of sliding of the housing onto a rack for mounting the electronic device and a latch section selectively projecting from a surface of the housing to lock the hook member at a predetermined position of a slidable movement of the hook member along a side surface of the housing.

An embodiment includes a method of manufacture of an electronic device where the method includes providing a pair of rack columns, attaching or fixing a housing of the electronic device to the pair of rack columns, forming a pair of hook members adapted on side surfaces of the housing to adjustably slide to engage and release the housing relative to the pair of rack columns.

When the structure of the latch section according to this embodiment is employed, the workability of mounting the electronic device on the rack columns and removing the electronic device from the rack columns is further improved.

Although the embodiments of the present invention are described herein with particularities, feature(s) thereof do not imply any limitation with respect to any of the embodiments. Many other variations and modifications will be apparent to those skilled in the art.

Moreover, although a few descriptions of a shape of a latch section are described herein, the present invention is not limited to any particular shape.

All examples and conditional language recited herein are intended for pedagogical purposes to aid the reader in understanding the aspects of the invention and the concepts contributed by the inventor to furthering the art, and are to be construed as being without limitation to such specifically recited examples and conditions, nor does the organization of such examples in the specification relate to a showing of the superiority and inferiority of the aspects of the invention. Although the embodiment in accordance with aspects of the present invention has been described in detail, it should be understood that various changes, substitutions, and alterations could be made hereto without departing from the spirit and scope of the invention.

Moreover, the term “or” is intended to mean an inclusive “or” rather than an exclusive “or”. That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form. Further, since numerous modifications and changes will readily occur to those skilled in the art, it is not desired to limit the invention to the exact construction and operation illustrated and described for the disclosed embodiments, and accordingly all suitable modifications and equivalents may be resorted to, falling within the scope of the claimed invention. It will further be understood that the phrase “at least one of A, B and C” may be used herein as an alternative expression that means “one or more of A, B and C.”

Although a few embodiments have been shown and described, it would be appreciated by those skilled in the art that changes may be made in these embodiments without departing from the principles and spirit of the invention, the scope of which is defined in the claims and their equivalents.

What is claimed is:

1. An electronic device, comprising
a housing attachable to a pair of rack columns; and
a pair of hook members adapted on side surfaces of the housing to adjustably slide to engage and release the housing relative to the pair of rack columns.

2. The electronic device according to claim 1, wherein the electronic device is fixed to the pair of rack columns that are erected and separated by a certain distance,
each side surfaces of the housing opposing one of the rack columns when the housing is sandwiched between the pair of rack columns to which the electronic device is fixed using mounting holes of the rack columns; and
the pair of hook members are supported slidably in a depth direction on the side surfaces, respectively, and engaged with the mounting holes of the rack columns, respectively.

3. The electronic device according to claim 2, wherein
each of the side surfaces includes:
a first surface;
a top rail having a hook shape and extending in the depth direction, that erects on the first surface from an upper edge of the first surface and is folded downwardly and hangs parallel to the first surface; and
a bottom rail having a hook shape and extending in the depth direction, that erects on the first surface from a lower edge of the first surface, and is folded upwardly and rises parallel to the first surface,
each of the hook members includes:
a slide plate that is received slidably in the depth direction between the first surface, and the top rail and the bottom rail; and
a hook plate that is substantially vertical to the first surface, erects on the slide plate, and provided with a hook hooked on the mounting hole of the rack column.

4. The electronic device according to claim 3, wherein each of the side surfaces includes a first latch section that unslidably and removably keeps the hook member in a first position that is located at a far side of the side surface.

5. The electronic device according to claim 4, wherein each of the side surfaces includes a second latch section that unslidably and removably keeps the hook member in a second position that is located at a front side of the side surface, and
each of the hook members being located at the second position when the electronic device is pushed towards the pair of rack columns into a fixed position.

6. An electronic device-housing body, comprising:
an electronic device-housing rack including a pair of rack columns that are separated by a certain distance; and
an electronic device fixed to the rack columns, and wherein
the electronic device includes:
a housing that includes side surfaces, each of the side surfaces opposing one of the rack columns when the housing is sandwiched between the pair of rack columns; and
a pair of hook members that are supported slidably in a depth direction on the side surfaces, respectively, and engaged with the mounting hole of the rack columns, respectively.

7. A housing of an electronic device, comprising
a hook member provided on a leading side of sliding of the housing onto a rack for mounting the electronic device; and
a latch section selectively projecting from a surface of the housing to lock the hook member at a predetermined position of a slidable movement of the hook member along a side surface of the housing.
